(19) United States
(12) Patent Application Publication
(10) Pub. No.: US 2012/0194984 A1
(43) Pub. Date: Aug. 2, 2012

(54) MOBILE TERMINAL

(75) Inventor: Toshiharu Aikawa, Kanagawa (JP)

(73) Assignee: PANASONIC CORPORATION, Osaka (JP)

(21) Appl. No.: 13/501,082

(22) PCT Filed: Oct. 14, 2010
(86) PCT No.: PCT/JP2010/006121

§ 371 Date: Apr. 9, 2012

(30) Foreign Application Priority Data
Oct. 14, 2009 (JP) 2009-237180

(51) Int. Cl. H05K 7/00

(52) U.S. Cl. 361/679.01

(57) ABSTRACT

A problem of the invention is to, while miniaturizing a coupling portion for coupling first and second cases constituting a portable terminal, prevent a cable that is passed through the coupling portion, from being raised, and fix the cable to the coupling portion with adjusting an extra length of the cable. The portable terminal of the invention includes: a first case; a second case; a coupling portion which swingably couples the first case and the second case to each other, and which includes a bearing portion that rotatably holds a shaft portion having a hollow portion; and a cable which is passed through the shaft portion. The coupling portion includes a fixing portion which clamps the cable that is passed through the hollow portion of the shaft member. The fixing portion includes: a notch portion which has a width that is smaller than the diameter of the cable, and into which the cable is clamped; and a hook portion which has a width that is smaller than the narrowest width of the notch portion, and which prevents the cable clamped into the notch portion, from slipping off.

### TECHNICAL FIELD

The present invention relates to a portable terminal in which first and second cases are swingably coupled to each other through a coupling portion.

### BACKGROUND ART

Conventionally, a foldable portable electronic apparatus in which a first case that has mainly an operating portion, and a second case that has mainly a liquid crystal screen are openable and closable through a hinge mechanism is known (for example, see Patent Reference 1). In a portable telephone disclosed in Patent Reference 1, a cable configured by a plurality of wires is laid in a coupling portion (hinge portion) of the portable telephone, and a connector portion which is connected to a circuit board disposed in a case constituting the portable telephone is disposed in the both ends of the cable. The coupling portion has a configuration in which a cable is laid so that twisting of the wires is not transmitted to the connector portion.

### PRIOR ART REFERENCE

### Patent Reference

Patent Reference 1: JP-A-2007-122195

### SUMMARY OF THE INVENTION

Problems that the Invention is to Solve

However, the portable telephone disclosed in Patent Reference 1 above does not have a configuration in which the cable is prevented from being raised in the coupling portion, and therefore there is a possibility that the cable is raised by a swinging operation of the hinge. In the case where a coupling part of a bearing member is miniaturized and the space for placing the cable is narrowed, particularly, the telephone is preferably configured so that, in addition to prevention of raising, an extra length of the cable can be adjusted before fixation to the coupling portion, in order to easily perform an assembling step.

It is an object of the invention to provide a portable terminal in which, while miniaturizing a coupling portion for coupling first and second cases constituting the portable terminal, a cable that is passed through the coupling portion can be prevented from being raised, and fixed to the coupling portion with adjusting an extra length of the cable.

### Means for Solving the Problems

The invention provides a portable terminal including: a first case; a second case; a coupling portion which swingably couples the first case and the second case to each other, and which includes: a shaft portion having a hollow portion; and a bearing portion that rotatably holds the shaft portion; and a cable which is passed through the shaft portion, wherein the coupling portion includes a fixing portion which clamps the cable that is passed through the hollow portion of the shaft member, and the fixing portion includes: a notch portion which has a width that is smaller than a diameter of the cable, and into which the cable is clamped; and a hook portion which has a width that is smaller than a narrowest width of the notch portion, and which prevents the cable clamped into the notch portion, from slipping off.

According to the configuration, while miniaturizing the coupling portion for coupling the first and second cases constituting the portable terminal, the cable that is passed through the coupling portion can be prevented from being raised, and fixed to the coupling portion with adjusting an extra length of the cable.

In the portable terminal, the coupling portion further includes a cover which is located between the hollow portion and the fixing portion, and which houses a part of the cable between the hollow portion and the fixing portion, in the coupling portion and in a space that is narrower than the diameter of the cable.

According to the configuration, even slight raising of the cable which is passed through the hollow portion of the shaft member can be prevented from occurring, and the cable can be fixed to the coupling portion.

### EFFECTS OF THE INVENTION

According to the portable terminal of the invention, while miniaturizing the coupling portion for coupling the first and second cases constituting the portable terminal, the cable that is passed through the coupling portion can be prevented from being raised, and fixed to the coupling portion with adjusting an extra length of the cable.

### BRIEF DESCRIPTION OF THE DRAWINGS

FIG. 1 is a perspective view showing the appearance of a portable telephone of an embodiment of the invention, (a) is a view showing a close state, (b) is a view showing a first open state, and (c) is a view showing a second open state.

FIG. 2 is a sectional view showing the center of a second hinge in FIG. 1(a).

FIG. 3 is a block diagram showing the electric configuration in a case of the portable telephone of the embodiment.

FIG. 4 is a perspective view of a swing shaft portion 41.

FIG. 5 is a perspective view of the swing shaft portion 41, as viewed from the rear side.

FIG. 6 is a perspective view of the swing shaft portion 41 to which a cable 32 is installed.

FIG. 7 is a plan view of a fixing portion 56, as viewed from the front side.

FIG. 8 is a perspective view showing a fixing structure for fixing the cable 32.

FIG. 9 is a sectional view (1) of a cover 70 to which the cable 32 is installed.

FIG. 10 is a sectional view (2) of the cover 70 to which the cable 32 is installed.

### MODE FOR CARRYING OUT THE INVENTION

Hereinafter, an embodiment of the invention will be described in detail with reference to the accompanying drawings. The description will be made while the portable terminal of the invention is applied to a foldable (openable) portable telephone.

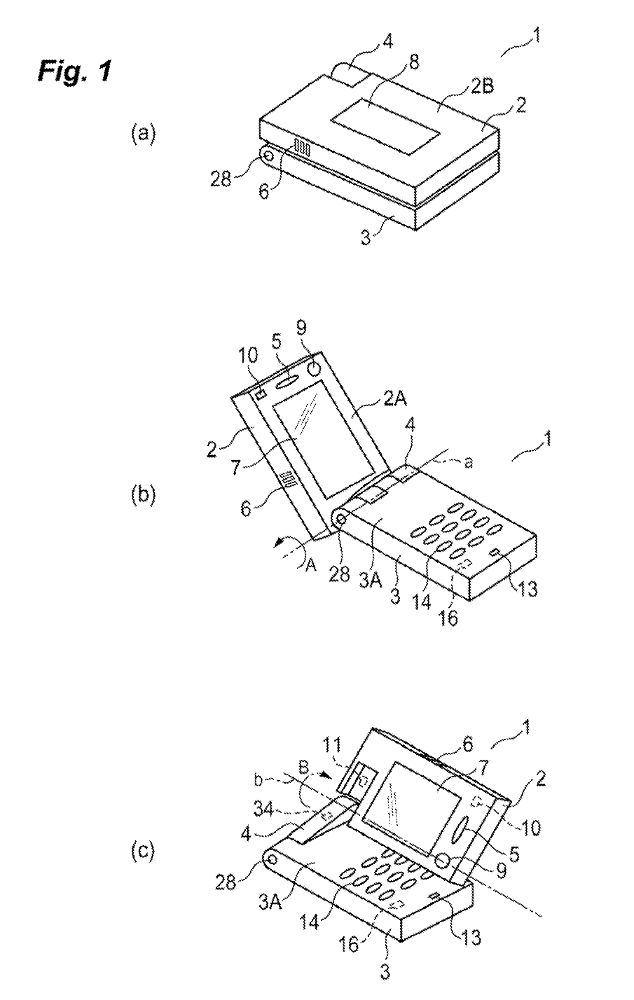

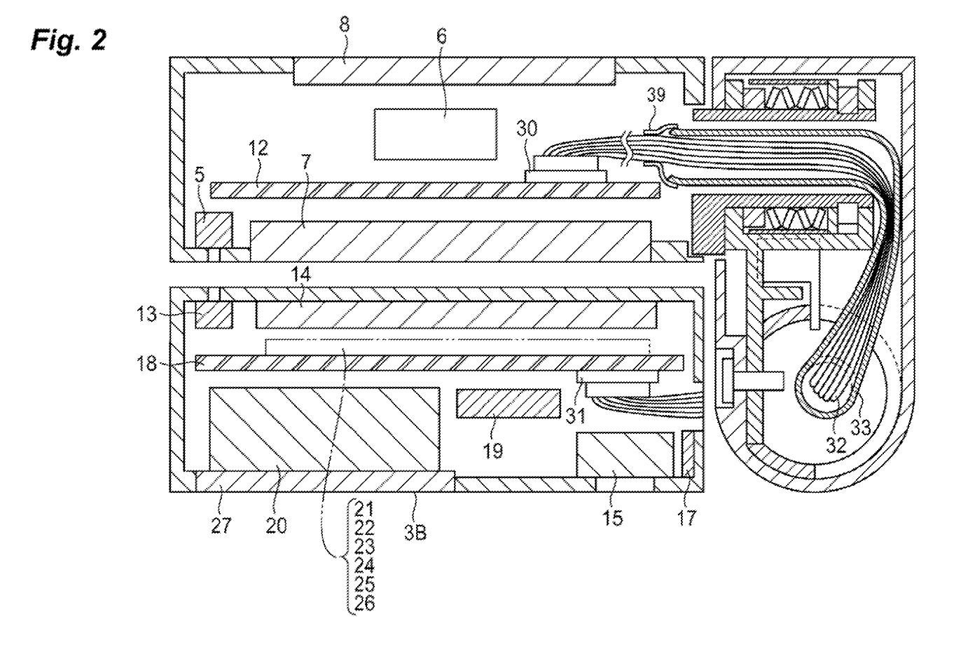

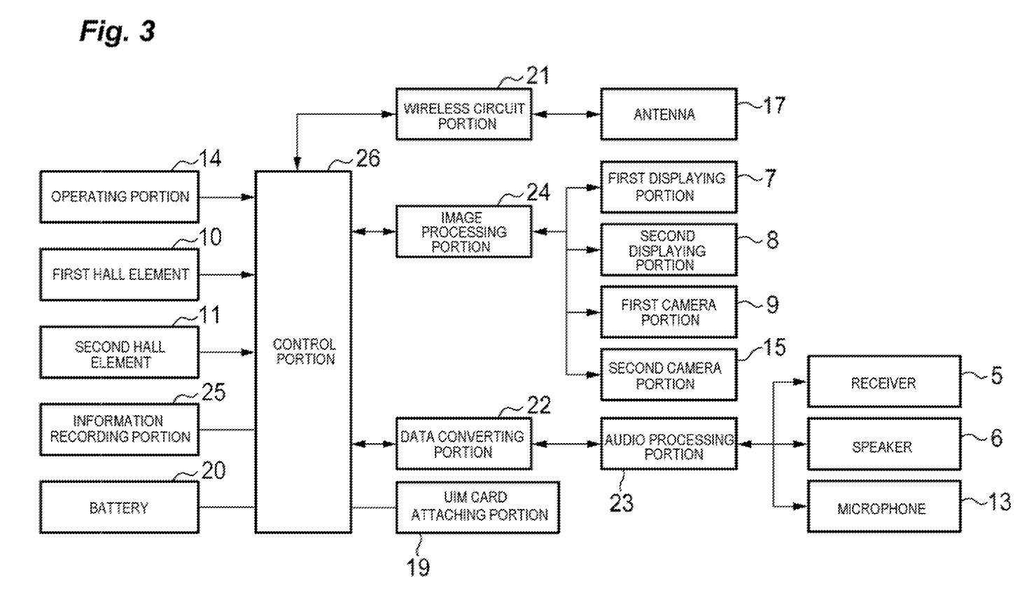

FIG. 1 is a perspective view showing the appearance of an openable portable telephone 1 (hereinafter, referred to as the portable terminal 1) of the embodiment of the invention, (a) is a view showing a close state, (b) is a view showing a first open state, and (c) is a view showing a second open state. FIG. 2 is a sectional view showing the center of a second hinge in FIG. 1(a). FIG. 3 is a block diagram showing the electric configuration in a case of the openable portable telephone of the embodiment of the invention.

As shown in FIG. 1, as a schematic configuration, the portable terminal 1 of the embodiment includes: a substantially box-like upper case 2 (a second case); a substantially box-like lower case 3 (a first case); and a coupling portion 4 which openably and closably couples the upper case 2 and the lower case 3 together. The portable terminal 1 is coupled so as to be openable and closable about an axis a in the direction (first direction) of arrow A, and perpendicular to the direction of arrow A about an axis b in the direction (second direction) of arrow B by a swinging operation of the coupling portion 4.

When to be carried, as shown in FIG. 1(a), the portable terminal 1 is used in an overlapped state (a closed state or a close state) where the upper case 2 and lower case 3 constituting the portable telephone are overlapped each other. In the case where a call is to be made, or characters, numerals, or a telephone number is to be input, for example, the portable terminal 1 is used in a first opened state (a first open state or a longitudinally opened state) where the upper case 2 is swung with respect to the lower case 3 about the axis a in the direction of arrow A (or the first direction) as shown in FIG. 1(b). In the case where a TV is to be viewed on a laterally elongated screen, for example, the portable terminal 1 is used in a second opened state (a second open state or a laterally opened state) where the upper case 2 is swung from the close state with respect to the lower case 3 about the axis b in the direction of arrow B (or the second direction, and a direction which is perpendicular to the first direction) as shown in FIG. 1(c).

Next, the configurations of the portable terminal of the openable portable telephone of the embodiment will be described with reference to FIGS. 1 to 3.

The upper case 2 houses a receiver 5, a speaker 6, a first displaying portion 7, a second displaying portion 8, a first camera portion 9, a first Hall element 10 and second Hall element 11 which are used as magnetic detecting elements, and a first printed circuit board 12 which is a first electric circuit portion. The first displaying portion 7 is disposed on the principal surface 2A of the upper case 2. The second displaying portion 8 is disposed on the rear surface 2B which is opposite to the principal surface 2A.

The lower case 3 houses a mouthpiece portion (microphone) 13, an operating portion 14, a second camera portion 15, a first magnet 16, an antenna 17, a second printed circuit board 18 which is a second electric circuit portion, a UIM card attaching portion 19, a detachable battery 20, and the like. A wireless circuit portion 21, a data converting portion 22, an audio processing portion 23, an image processing portion 24, an information recording portion 25, a controlling portion 26, and the like (in FIG. 2, indicated by the dash-dot-dash line) are mounted on the second printed circuit board 18. In the second printed circuit board 18, a feeding portion (not shown) is formed, and the antenna 17 is connected to the feeding portion. The operating portion 14 which is exposed when the portable terminal 1 is in the first or second open state is disposed on the principal surface 3A of the lower case 3. A UIM (User Identity Module) card that is used as an IC card on which information of the subscriber, telephone number information, personal identifying information, and the like are recorded is attached to the UIM card attaching portion 19 which is placed adjacently to the battery 20, and can be replaced (inserted or extracted) in a state where a battery cover 27 which covers the battery 20, and the battery 20 are detached. The battery cover 27 constitutes a part of the back surface 3B which is opposite to the principal surface 3A, and is detachable.

The coupling portion 4 to which a first coupling portion 28 and a second coupling portion 29 are attached swingably couples the upper case 2 and the lower case 3 together. A flexible wiring member (cable) 32 in which one end is inserted into a first connector 30 disposed on the surface of the first printed circuit board 12, and the other end is inserted into a second connector 31 disposed on the surface of the second printed circuit board 18, and which electrically connects the first printed circuit board 12 to the second printed circuit board 18 is passed through the coupling portion 4. The cable 32 includes a plurality of wires, and passed through a tubular pipe member 33 which is formed by fibers such as polyester. A second magnet 34 is disposed inside the coupling portion 4 so as to be opposed to the second Hall element 11 when the portable telephone is in the close state or the first open state.

Next, the lower case 3 will be described in detail. The microphone 13 is disposed in the principal surface 3A of the lower case 3 so as to, when the portable terminal 1 is in the close state, be opposed to and covered by the upper case 2, and, when the portable terminal 1 is in the first or second open state, be exposed. In a calling operation, a voice of the user is transmitted to a communication counterparty.

The operating portion 14 is placed in the principal surface 3A of the lower case 3. Numerals, characters, and symbols are printed in order to allow a telephone number or characters to be input. The operating portion includes, for example, a plurality of operation buttons through which call reception, call termination, adjustment of the volume which is output through the receiver 5 or the speaker 6, switching to the vibration mode, selection and determination on a menu screen, and the like can be performed.

The second camera portion 15 is disposed on the side of the back surface 3B which is opposite to the principal surface 3A, and in close proximity to the second printed circuit board 18, and, when the portable telephone is in the first open state, can take an image of the rear of the first displaying portion 7. When the object is in front of the user, it is possible to, while taking an image, check the taken image displayed on the first displaying portion 7.

In both the second camera portion 15 and the first camera portion 9 which has been described above, incident light from the captured subject is passed through a lens group, and the optical signal is converted to an electric signal by a photoelectric converting element such as a CCD (Charge Coupled Device) to produce image information. The image information is processes by the image processing portion 24, and then an image is produced on the first displaying portion 7. The taken image may be recorded together with the telephone number in the telephone directory. In the case where an incoming call is received from a counterparty whose image is stored, when the portable terminal 1 is in the close state, the image correlated with the corresponding telephone number is displayed on the second displaying portion 8, and, when the portable terminal 1 is in the first or second open state, the image is displayed on the first displaying portion 7. When the correlated image is a face image, it is possible to easily (at a glance) identify the calling party.

Therefore, the first displaying portion 7, the second displaying portion 8, the first camera portion 9, and the second camera portion 15 are connected to the image processing portion 24, and, when a predetermined operation is performed, the image information taken by the first displaying portion 7 and the second camera portion 15 is recorded in the information recording portion 25. The information recording portion 25 can record telephone number information, audio information, other image information (received image information, and the like), and text information such as a mail in preparation and transmitted/received mails, in addition to the image information taken by the first camera portion 9 and the second camera portion 15.

The antenna 17 is placed in the lower case 3. The antenna 17 exhibits a resonance point in any one of a 900-MHz band, 1.8-GHz band, and 1.9-GHz band which are bands for the GSM system, and a 2-GHz band which is a band for the W-CDMA system, and can perform transmission and reception in any one of or a plurality of the bands. The antenna 17 may be used also for receiving a digital television broadcast, a radio broadcast, or the like, or as a transmitting and receiving antenna for short-range wireless communication.

The second printed circuit board 18 is disposed below the operating portion 14 and in the vicinity of the second camera portion 15, and, in a part, includes connectors (not shown) which are connected to the UIM card attaching portion 19 and the battery 20.

The controlling portion 26 is connected to the operating portion 14, the first Hall element 10, the second Hall element 11, the wireless circuit portion 21, the data converting portion 22, the image processing portion 24, and the information recording portion 25, and controls these portions. The controlling portion 26 is connected also to the UIM card attaching portion 19 and the battery 20.

The wireless circuit portion 21 is connected to the antenna 17, and configured so as to process data received by the antenna 17 and output the processed data to the data converting portion 22. The data converting portion 22 is connected to the audio processing portion 23, and the audio processing portion 23 is connected to the receiver 5, the speaker 6, and the microphone 13.

Therefore, the data converting portion 22 converts received data from the antenna 17 through the wireless circuit portion 21 and the controlling portion 26, into audio data, and outputs the audio data to the audio processing portion 23.

The audio processing portion 23 decodes the audio data to produce an audio signal, and then outputs the audio signal to the receiver 5 and the speaker 6. The receiver 5 and the speaker 6 output sound corresponding to the audio signal transmitted from the audio processing portion 23.

Furthermore, the audio processing portion 23 encodes the sound received by the microphone 13 to produce audio data, and then outputs the audio data to the data converting portion 22. The data converting portion 22 converts the input audio data into communication data, and then outputs the communication data to the wireless circuit portion 21. The wireless circuit portion 21 processes the received communication data, and transmits the processed data as a radio wave of a wireless signal from the antenna 17.

Next, the first Hall element 10 and the second Hall element 11 will be described. When the portable terminal 1 is in the close state, the first magnet 16 is in close proximity to the first Hall element 10, the element therefore detects the magnetic field of the first magnet 16, and outputs a detection signal to the controlling portion 26. When the portable terminal 1 is in the first open state and the second open state, the first magnet 16 is separated from the first Hall element 10, the magnetic field of the first magnet 16 cannot therefore be detected, and hence the first Hall element 10 does not produce a detection signal.

When the portable terminal 1 is in the close state and the first open state, the second magnet 34 is in close proximity to the second Hall element 11, the element therefore detects the magnetic field of the second magnet 34, and outputs a detection signal to the controlling portion 26. When the portable terminal 1 is in the second open state, the second magnet 34 is remotely separated from the second Hall element 11, the magnetic field of the second magnet 34 cannot therefore be detected, and hence the second Hall element 11 does not produce a detection signal.

When the first Hall element 10 detects the first magnet 16 and the second Hall element 11 detects the second magnet 34, namely, the portable terminal 1 is in the first close state. When the first Hall element 10 does not detect the first magnet 16 and the second Hall element 11 detects the second magnet 34, the portable terminal 1 is in the first open state. When the first Hall element 10 does not detect the first magnet 16 and also the second Hall element 11 does not detect the second magnet 34, the portable terminal 1 is in the second open state.

When the portable terminal 1 is set from the close state to the first open state or the second open state, the operating portion 14 and the first displaying portion 7 are exposed, a light source for illuminating the operating portion 14, and that for illuminating the first displaying portion 7 are turned on. When the operating portion is not operated for a predetermined time period, the light sources are turned off. When the portable terminal 1 is set from the opened state to the close state, both the light sources for illuminating the operating portion 14 and the first displaying portion 7 are turned off, thereby reducing the power consumption. In the case where an incoming call is received during a period when the portable terminal 1 is in the close state, information of the counterparty is displayed on the second displaying portion 8. When the user sets the portable terminal 1 to the first open state in order to perform the receiving operation, for example, the information which has been displayed on the second displaying portion 8 is not displayed, and instead displayed on the first displaying portion 7. In this way, various display manners are controlled depending on the mode of the portable terminal 1.

The cable 32 electrically connects the first printed circuit board 12 to the second printed circuit board 18. In accordance with the control by the controlling portion 26, the signal which causes a sound to be output from the receiver 5 or the speaker 6, that which causes images taken by the first camera portion 9 and the second camera portion 15 to be displayed on the first displaying portion 7, and the like are transmitted and received. The both ends of the pipe member 33 are fixed to the cable 32 by a tape 39 (in FIG. 2, only one end is illustrated). The pipe member 33 can expand and contract. When installed into the portable terminal 1, therefore, the pipe member 33 is fixed in order to prevent the pipe member from being arbitrarily moved with respect to the cable 32. Hereinafter, it is assume that the cable 32 is housed in the pipe member 33.

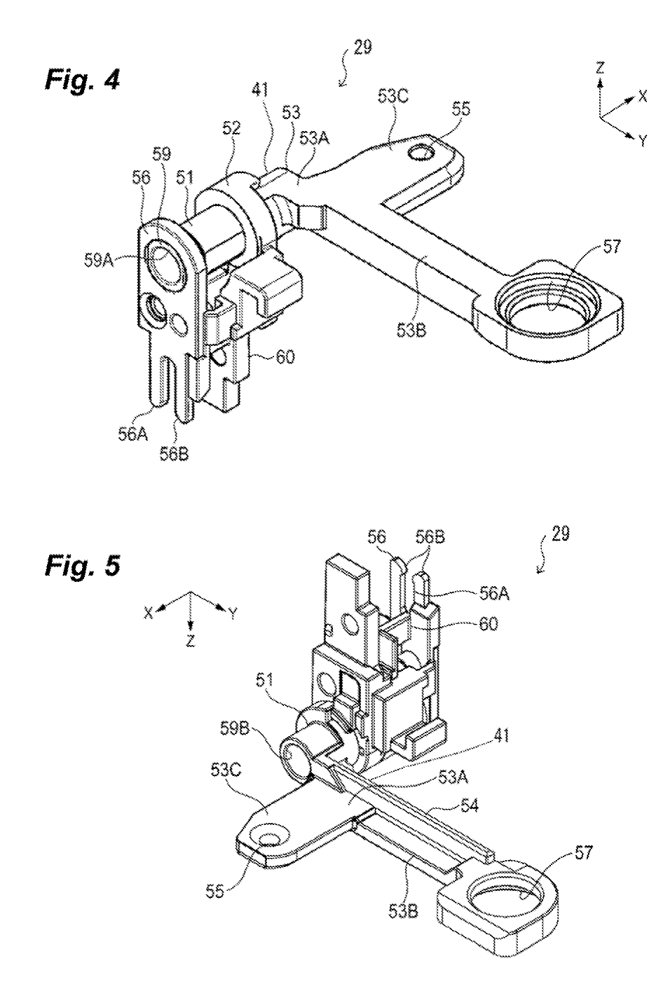

Next, the coupling portion 4 will be described in detail with reference to FIGS. 4 and 5. FIG. 4 is a perspective view of a swing shaft portion 41, and FIG. 5 is a perspective view of the swing shaft portion 41, as viewed from the rear side. As shown in FIG. 4, the second coupling portion 29 which is housed in the coupling portion 4 includes the swing shaft portion 41 and an attaching portion 60.

The swing shaft portion 41 has: a small-diameter portion 51; a large-diameter portion 52 in which the diameter is larger than that of the small-diameter portion 51; an arm portion 53 which is formed perpendicularly to the large-diameter portion 52; a first screw hole portion 55, and second screw hole portion 57 which are formed in the arm portion 53, and which are fixed to the upper case 2 by screws; a first through hole 59 which is passed through the small-diameter portion 51 and the large-diameter portion 52, and which extends in the longitudinal direction of the case (in FIG. 4, the X-axis); a fixing portion 56 for fixing the cable 32 which is passed through the first through hole 59; and the attaching portion 60 for attaching the swing shaft portion 41 to a bearing member 80 which is unswingably attached to the lower case 3. The large-diameter portion 52 is formed between the small-diameter portion 51 and the arm portion 53.

As shown in FIG. 4, the arm portion 53 includes: a basal portion 53A which is connected to the large-diameter portion 52; a first extending portion 53B which extends from the basal portion 53A in the short direction (in the figure, the Y-axis direction) of the upper case 2; and a second extending portion 53C which extends from the basal portion 53A in the longitudinal direction (in the figure, the X-axis direction) of the upper case 2. The second screw hole portion 57 which is fixed to the upper case 2 by a screw is disposed in the tip end of the first extending portion 53B, and the first screw hole portion 55 which is fixed to the upper case 2 by a screw is disposed in the tip end of the second extending portion 53C.

As shown in FIG. 5, the arm portion 53 is formed into a substantially L-like shape as viewed in the thickness direction (in the figure, the Z-axis direction) of the upper case 2. Then, a rib 54 which is formed into a substantially L-like shape is disposed on one-side surfaces of the basal portion 53A and the first extending portion 53B. In the short direction (in the figure, the Y-axis direction) of the upper case 2, the rib 54 extends from an end part of the basal portion 53A which is close to the small-diameter portion 51, to the tip end of the first extending portion 53B.

As shown in FIG. 4, in an upper portion of the fixing portion 56, the first through hole 59 which extends in the longitudinal direction of the case (in the figure, the X-axis), and which is passed through the small-diameter portion 51 and the large-diameter portion 52 is formed. One opening 59A is formed in the first through hole 59 on the side of the fixing portion 56, and the other opening 59B is formed in the first through hole 59 on the side of the basal portion 53A (see FIGS. 4 and 5).

In a lower portion of the fixing portion 56, a notch portion 56A, and a hook portion 56B which is formed in the tip end of the notch portion 56A are formed. The notch portion 56A holds the cable 32 which is passed from the opening 59B through the first through hole 59 to leave from the opening 59A. The hook portion 56B prevents the cable 32 held by the notch portion 56A, from slipping off. In the fixing portion 56, the cable 32 is held by the notch portion 56A, and the hook portion 56B prevents the cable 32 held by the notch portion 56A, from slipping off, whereby the cable 32 can be fixed.

Next, the configuration of the fixing portion 56 will be described with reference to FIG. 7. FIG. 7 is a plan view of the fixing portion 56, as viewed from the front side. As shown in FIG. 7, the notch portion 56A is formed by cutting away the fixing portion 56 in a tapered manner. The width W1 of the notch portion 56A is more narrowed as further advancing from an upper portion of the fixing portion 56 toward a lower portion in the thickness direction (in the figure, the Z-axis direction) of the case. The hook portion 56B which is projected toward the upper portion of the fixing portion 56 is formed in the both tip end portions of the notch portion 56A which is bifurcated. The width W2 of the hook portion 56B is set to be slightly narrower than the narrowest width of the width W1 of the notch portion 56A. Therefore, the hook portion 56B can perform slipping-off prevention so as to prevent the cable 32 which is once inserted into the notch portion 56A, from slipping off of the notch portion 56A. The hook portion 56B may have a shape which is bilaterally symmetric. The cable 32 is covered by the pipe member 33, and hence is not damaged by the fixing portion 56.

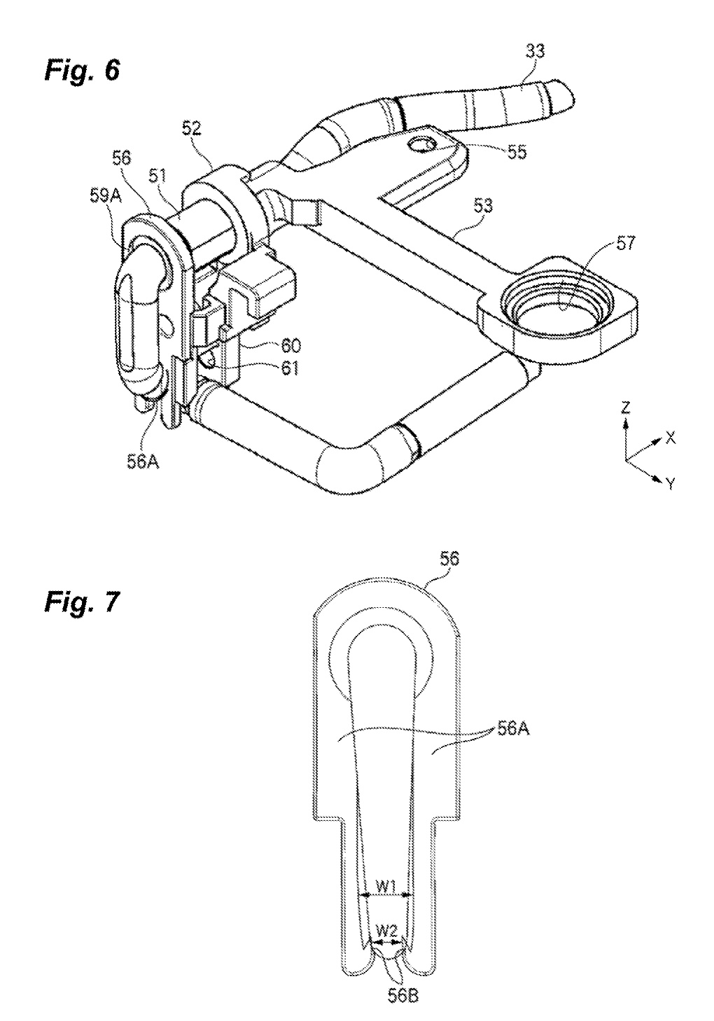

A method of installing the cable 32 to the swing shaft portion 41 will be described with reference to FIG. 6. FIG. 6 is a perspective view of the swing shaft portion 41 to which the cable 32 is installed.

As shown in FIG. 6, the cable 32 enters the first through hole 59 through the one opening 59B formed in the small-diameter portion 51, and leaves from the other opening 59A formed in the upper portion of the fixing portion 56. Then, the cable 32 which leaves from the opening 59A of the upper portion of the fixing portion 56 downward extends along the thickness direction (in the figure, the Z-axis direction) of the case, and is held by the notch portion 56A of the lower portion of the fixing portion 56. At this time, the cable 32 is held by the notch portion 56A, and further prevented by the hook portion 56B from slipping off. Therefore, the cable 32 is surely fixed by the fixing portion 56 without being raised.

When the cable 32 is to be installed to the second coupling portion 29, the cable 32 which leaves from the other opening 59A of the fixing portion 56 downward extends along the thickness direction (in the figure, the Z-axis direction) of the case, and is held by the notch portion 56A formed in the lower portion of the fixing portion 56. Therefore, the cable 32 can be easily installed. Namely, the cable 32 is hooked by the notch portion 56A of the fixing portion 56, whereby the cable 32 can be fixed, and the assembling can be performed without adjusting an extra length of the cable 32.

As shown in FIG. 6, the attaching portion 60 has a screw hole portion 61 which is fixed to the bearing member 80 by a screw. The attaching portion 60 swingably holds and supports the small-diameter portion 51 of the swing shaft portion 41, thereby enabling the swing shaft portion 41 to be swingably attached to the attaching portion 60.

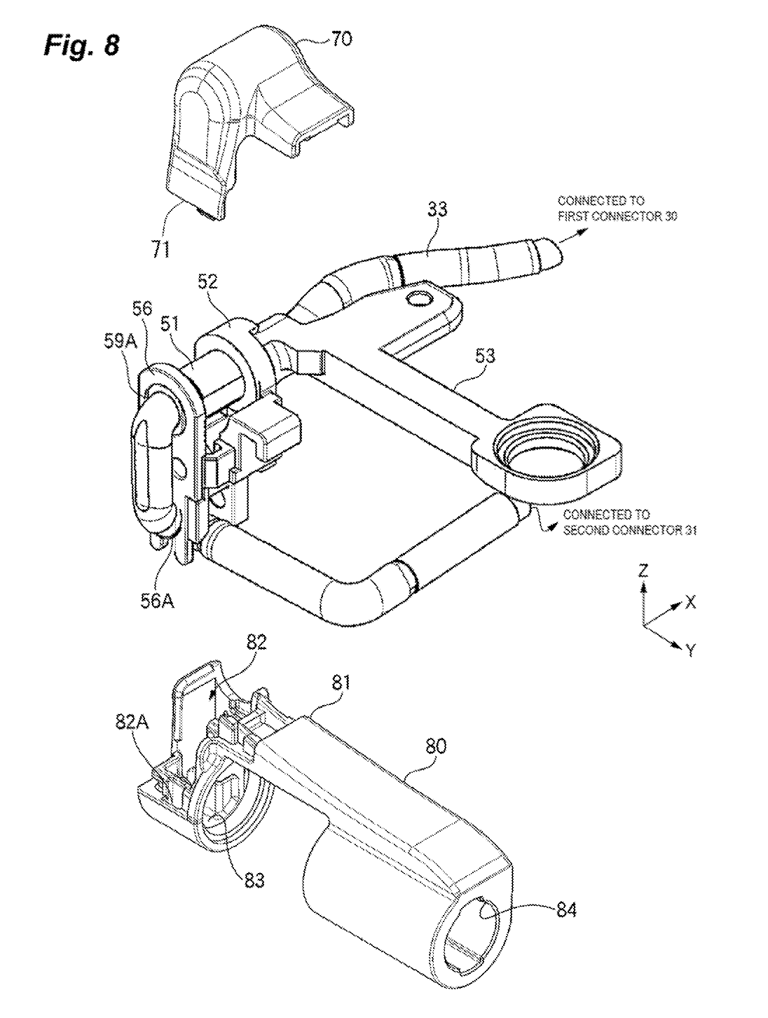

The fixing structure for fixing the cable 32 will be described with reference to FIG. 8. FIG. 8 is a perspective view showing the fixing structure for fixing the cable 32. As shown in FIG. 8, the bearing member 80 which forms the first coupling portion 28 includes: a bearing body portion 81; a first housing portion 82 which is coupled to the bearing body portion 81, and which houses the attaching portion 60; and a second housing portion 84 which is coupled to the bearing body portion 81, and which houses the first coupling portion 28. An opening 83 for passing through the cable 32 is disposed in the side surface of the first housing portion 82.

A cover 70 is engaged with the first housing portion 82 by engaging an engaging claw 71 with an engaging hole 82A of the first housing portion 82. The cover 70 covers the cable 32 which leaves from the opening 59A, and which is held by the notch portion 56A, so as not to be exposed to the outside. Therefore, the appearance quality of the portable terminal 1 is not lowered.

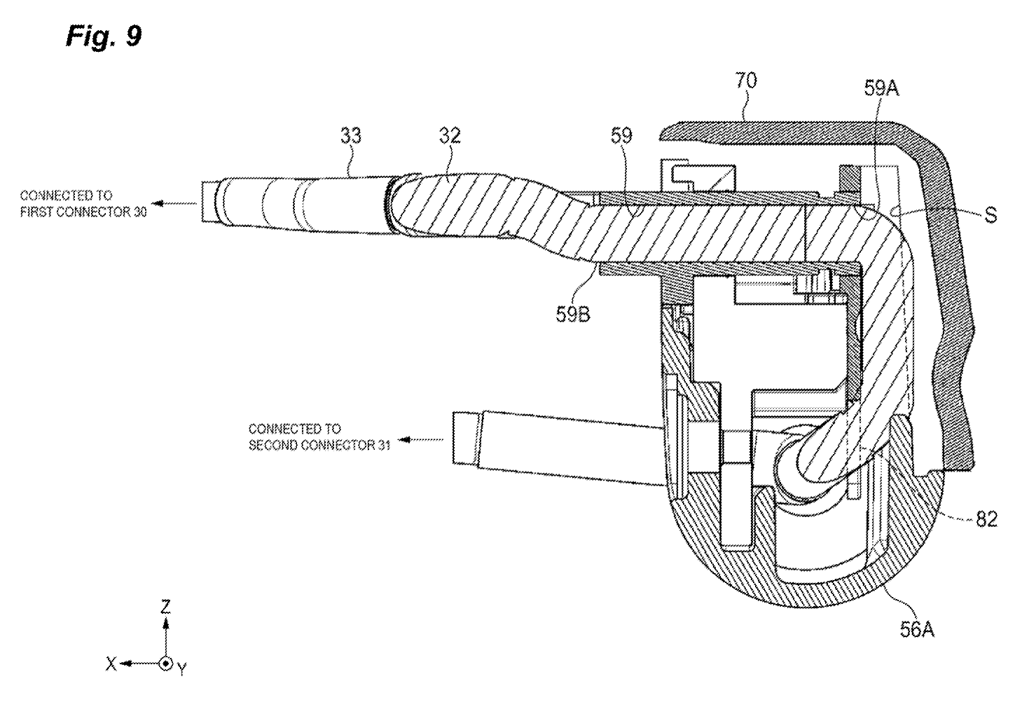

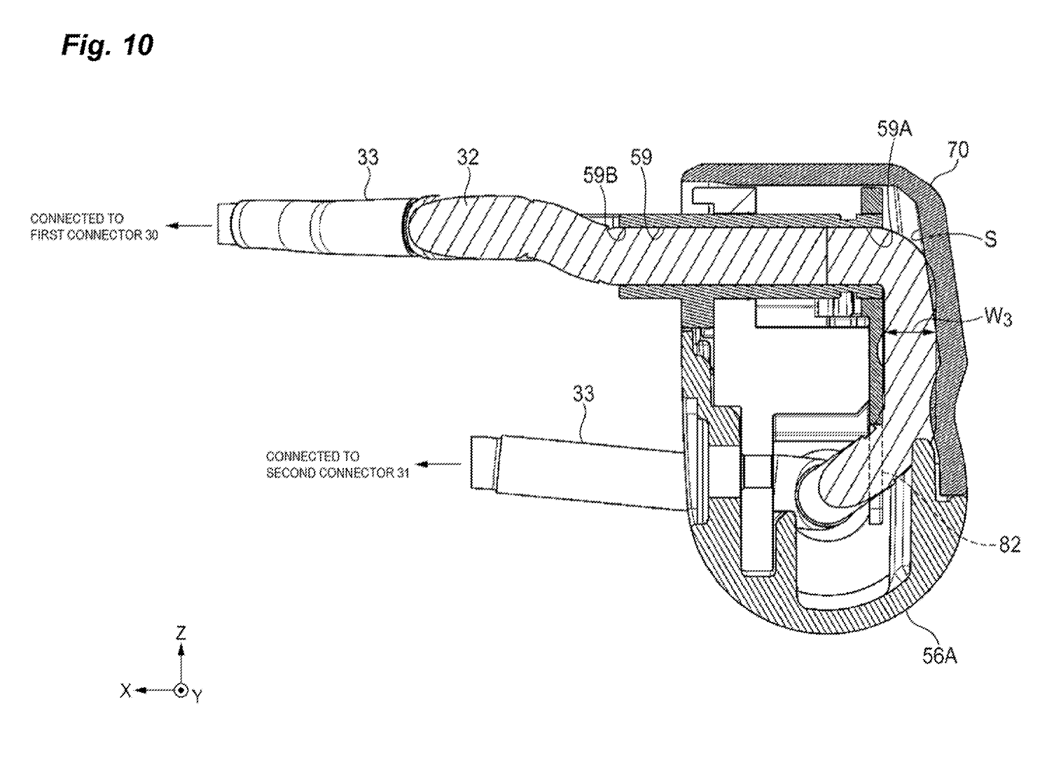

A method of installing the cover 70 will be described with reference to FIGS. 9 and 10. FIG. 9 is a sectional view (1) of the cover 70 to which the cable 32 is installed, and FIG. 10 is a sectional view (2) of the cover 70 to which the cable 32 is installed. In FIGS. 9 and 10, for the sake of description, the cable 32 in the pipe member 33 is indicated by the hatched portion.

As shown in FIG. 9, the cable 32 which is connected to the first connector 30 enters the first through hole 59 through the opening 59B, and leaves from the other opening 59A formed in the upper portion of the fixing portion 56. Then, the cable 32 which leaves from the opening 59A of the upper portion of the fixing portion 56 downward extends along the thickness direction (in the figure, the Z-axis direction) of the case, and is held by the notch portion 56A of the lower portion of the fixing portion 56. The cable 32 which is held by the notch portion 56A is prevented by the hook portion 56B from slipping off of the notch portion 56A. Therefore, the cable 32 can be fixed by hooking the cable 32 on the notch portion 56A of the fixing portion 56, thereby enabling the assembling to be performed without adjusting an extra length of the cable 32. Then, the cable 32 which is held by the notch portion 56A is passed through the interior of the first housing portion 82 of the bearing member 80 which is attached to the lower case 3, leaves from the opening 83, and is connected to the second connector 31.

As shown in FIG. 9, furthermore, the cable 32 which leaves from the opening 59A is held by the notch portion 56A, and further prevented from slipping off by the hook portion 56B. Therefore, the cable 32 is not raised, and is surely fixed by the fixing portion 56. However, the cable 32 which leaves from the opening 59A in the upper portion of the fixing portion 56 is raised toward the outside although in a slight degree. As shown in FIG. 10, therefore, the cover 70 is engaged with the first housing portion 82, covers the cable 32, and causes the cable 32 to be housed in a space S having a width W3 which is slightly smaller than the diameter of the cable 32. Therefore, even slight raising of the cable 32 can be prevented by the cover 70 from occurring.

Moreover, since the cable 32 which leaves from the opening 59A, and which is held by the notch portion 56A is covered by the cover 70, the cable 32 is not exposed to the outside, and the appearance quality is not impaired.

As described above, in the portable terminal 1 of the embodiment, the cable 32 is held by the notch portion 56A of the fixing portion 56 which constitutes a part of the coupling portion 4, and the cable 32 is prevented from slipping off by the hook portion 56B. Therefore, raising of the cable 32 can be prevented from occurring in the coupling portion 4, and the cable 32 can be fixed to the coupling portion 4.

In the portable terminal 1 of the embodiment, moreover, the cable 32 can be fixed by hooking the cable 32 with the notch portion 56A of the fixing portion 56 which constitutes a part of the coupling portion 4, and the cable 32 can be installed to the coupling portion 4 without adjusting an extra length of the cable 32.

In the portable terminal 1 of the embodiment, moreover, the cover 70 is engaged with the first housing portion 82 in the coupling portion 4 to cover the cable 32 which is exposed to the outside, thereby causing the cable 32 which leaves from the opening 59A, and which is held by the notch portion 56A, to be housed in the space S having the width W3 which is slightly smaller than the diameter of the cable 32. Therefore, even slight raising of the cable 32 can be prevented by the cover 70 from occurring.

In the portable terminal 1 of the embodiment, moreover, the cover 70 is engaged with the first housing portion 82 in the coupling portion 4 to cover the cable 32 which is exposed to the outside, and hence the appearance quality is not impaired.

Although the invention has been described in detail and with reference to the specific embodiment, it is obvious to those skilled in the art that various changes and modifications can be made without departing from the spirit and scope of the invention.

The application is based on Japanese Patent Application (No. 2009-237180) filed Oct. 14, 2009, and its disclosure is incorporated herein by reference.

### INDUSTRIAL APPLICABILITY

The portable terminal of the invention has an effect that, while miniaturizing the coupling portion for coupling the first and second cases constituting the portable terminal, the cable that is passed through the coupling portion can be prevented from being raised, and fixed to the coupling portion with adjusting an extra length of the cable, and is useful as a portable telephone or the like.

### DESCRIPTION OF REFERENCE NUMERALS AND SIGNS

1 openable portable telephone (portable terminal)
2 upper case (second case)
3 lower case (first case)
4 coupling portion
12 first printed circuit board
18 second printed circuit board
29 second coupling portion
30 first connector
31 second connector
32 cable
41 swing shaft portion
53 arm portion
53A basal portion
53B first extending portion
53C second extending portion
54 rib
55 first screw hole portion
56 fixing portion
56A notch portion
56B hook portion
57 second screw hole portion
59 first through hole
59A, 59B opening
60 attaching portion
80 bearing member

1. A portable terminal comprising:
a first case;
a second case;
a coupling portion which swingably couples the first case and the second case to each other, and which includes: a shaft portion having a hollow portion; and a bearing portion that rotatably holds the shaft portion; and
a cable which is passed through the shaft portion, wherein
the coupling portion includes a fixing portion which clamps the cable that is passed through the hollow portion of the shaft member, and
the fixing portion includes: a notch portion which has a width that is smaller than a diameter of the cable, and into which the cable is clamped; and
a hook portion which has a width that is smaller than a narrowest width of the notch portion, and which prevents the cable clamped into the notch portion, from slipping off.

2. A portable terminal according to claim 1, wherein
the coupling portion further includes
a cover which is located between the hollow portion and the fixing portion, and which houses a part of the cable between the hollow portion and the fixing portion, in the coupling portion and in a space that is narrower than the diameter of the cable.

3. A portable terminal including:
a first case;
a second case;
a coupling portion which swingably couples the first case and the second case to each other, and which includes: a shaft portion having a hollow portion; and a bearing portion that rotatably holds the shaft portion; and
a cable which is passed through the shaft portion, wherein
the coupling portion includes a fixing portion which clamps the cable that is passed through the hollow portion of the shaft member, and
a notch portion which is disposed in a lower portion of the fixing portion, which has a width that is smaller than a diameter of the cable, and into which the cable is clamped, and
a hook portion which, in a tip end of the notch portion, is projected toward an upper portion of the notch portion are included.

4. A portable terminal according to claim 3, wherein
the coupling portion further includes
a cover which is located between the hollow portion and the fixing portion, and which houses a part of the cable between the hollow portion and the fixing portion, in the coupling portion and in a space that is narrower than the diameter of the cable.
